(19) United States
(12) Patent Application Publication
(10) Pub. No.: US 2025/0190118 A1
(43) Pub. Date: Jun. 12, 2025

(54) STORAGE DEVICE

(71) Applicant: Samsung Electronics Co., Ltd., Suwon-si (KR)

(72) Inventors: Kil Ho LEE, Suwon-si (KR); Dae Shik KIM, Suwon-si (KR)

(21) Appl. No.: 18/796,596

(22) Filed: Aug. 7, 2024

(30) Foreign Application Priority Data
Dec. 11, 2023 (KR) 10-2023-0178896

(51) Int. Cl. G06F 3/06

(52) U.S. Cl. CPC G06F 3/0614; G06F 3/0656; G06F 3/0679

(57) ABSTRACT

A storage device includes a first buffer memory and a second buffer memory that are different from each other in at least one operation parameter, a non-volatile memory, and a storage controller connected to the first buffer memory, the second buffer memory, and the non-volatile memory and configured to perform communication with the first buffer memory, the second buffer memory and the non-volatile memory. Each of the first buffer memory and the second buffer memory includes Magnetic Random Access Memory (MRAM) cells and a peripheral circuit configured to operate the MRAM cells according to the at least one operation parameter.

### CROSS-REFERENCE TO RELATED APPLICATION

This application claims priority from Korean Patent Application No. 10-2023-0178896 filed on Dec. 11, 2023, in the Korean Intellectual Property Office and all the benefits accruing therefrom under 35 U.S.C. 119, the contents of which in its entirety are herein incorporated by reference.

### BACKGROUND

### Technical Field

The present disclosure relates to a storage device.

### Description of the Related Art

With high-speed and low-power of an electronic device, a memory device embedded in the electronic device requires fast read/write operations and low operating voltages. A magnetic memory device has been studied as a memory device that satisfies such requirements. The magnetic memory device is non-volatile and enables high-speed operation, and thus has been spotlighted as a next-generation memory.

Meanwhile, as a magnetic memory device is increasingly highly integrated, spin transfer torque-magnetoresistive random access memory (STT-MRAM) for storing information using a spin transfer torque (STT) phenomenon is being studied. The STT-MRAM may induce a magnetization reversal by applying a direct current to a magnetic tunnel junction element, thereby storing information. The highly integrated STT-MRAM requires a high-speed operation and a low current operation.

### BRIEF SUMMARY

An object of the present disclosure is to provide a storage device in which product reliability is improved.

The objects of the present disclosure are not limited to those mentioned above and additional objects of the present disclosure, which are not mentioned herein, will be clearly understood by those skilled in the art from the following description of the present disclosure.

According to an aspect of the present disclosure, a storage device includes a first buffer memory and a second buffer memory that are different from each other in at least one operation parameter, a non-volatile memory, and a storage controller connected to the first buffer memory, the second buffer memory, and the non-volatile memory and configured to perform communication with the first buffer memory, the second buffer memory and the non-volatile memory. Each of the first buffer memory and the second buffer memory includes Magnetic Random Access Memory (MRAM) cells and a peripheral circuit configured to operate the MRAM cells according to the at least one operation parameter.

According to an aspect of the present disclosure, a storage device includes a first buffer memory including first MRAM memory cells operating at a first operation parameter, a second buffer memory including second MRAM memory cells operating at a second operation parameter, a non-volatile memory, and a storage controller configured to store data, which is provided from a host, in one of the first buffer memory and the second buffer memory in accordance with an amount of the data provided from the host.

According to an aspect of the present disclosure, a storage device includes a first buffer memory including first MRAM memory cells operating at a first writing speed, a second buffer memory including second MRAM memory cells operating at a second writing speed, a non-volatile memory, and a storage controller configured to perform communication with the first buffer memory, the second buffer memory, and the non-volatile memory. The first writing speed is different from the second writing speed.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating a memory system according to some embodiments;

FIG. 2 is a block diagram illustrating a storage device of FIG. 1;

FIG. 3 is an exemplary block diagram illustrating a buffer memory of FIG. 1;

FIG. 4 is an exemplary circuit view illustrating a cell array of a buffer memory of FIG. 3;

FIG. 5 is an exemplary block diagram illustrating a non-volatile memory of FIG. 1;

FIG. 6 is a view illustrating a 3D V-NAND structure applicable to a non-volatile memory apparatus according to some embodiments;

FIG. 7 is a cross-sectional view illustrating a non-volatile memory of FIG. 1;

FIG. 8 is a block diagram illustrating a memory system according to some embodiments;

FIG. 9 is a flow chart illustrating an operation of a storage controller of FIG. 8;

FIGS. 10 and 11 are block diagrams illustrating a memory system according to some embodiments;

FIG. 12 is a block diagram illustrating a memory system according to some embodiments;

FIGS. 13 and 14 are block diagrams illustrating a memory system according to some embodiments;

FIG. 15 is a view illustrating a system according to some embodiments; and

FIG. 16 is a view illustrating a data center according to some embodiments.

### DETAILED DESCRIPTION OF THE DISCLOSURE

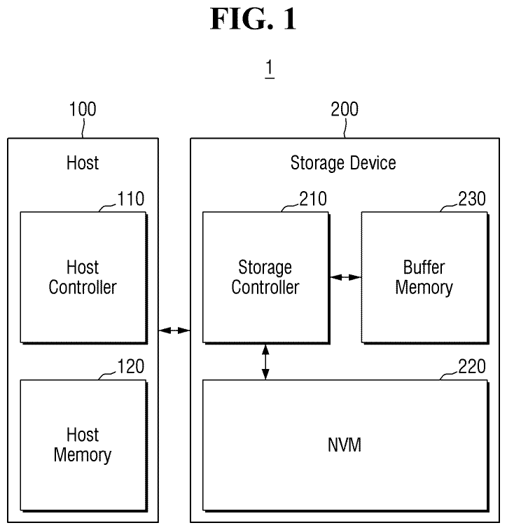

FIG. 1 is a block diagram illustrating a memory system according to some embodiments.

Referring to FIG. 1, a memory system 1 according to some embodiments may include a host device 100 and a storage device 200.

The host device 100 may include a host controller 110 and a host memory 120. The host controller 110 may manage an operation of storing data (e.g., write data) of a buffer region in a non-volatile memory 220 or storing data (e.g., read data) in the non-volatile memory 220. The host memory 120 may serve as a buffer memory for temporarily storing data to be transmitted to the storage device 200 or data transmitted from the storage device 200.

In some embodiments, the host controller 110 and the host memory 120 may be implemented as separate semiconductor chips. In some embodiments, the host controller 110 and the host memory 120 may be integrated in the same semiconductor chip. For example, the host controller 110 may be any one of a plurality of modules provided in an application processor, and the application processor may be implemented as a system on chip (SoC). In some embodiments, the host memory 120 may be an embedded memory provided in the application processor. For example, the host memory 120 may be integrated into a semiconductor chip in which the application processor is disposed. In some embodiments, the host memory 120 may be a non-volatile memory or a memory module disposed outside a semiconductor chip in which the application processor is disposed. The term “a semiconductor chip,” as used herein, refers to a die singulated from a wafer unless the context indicates otherwise.

The storage device 200 may include a storage controller 210, a non-volatile memory (NVM) 220, and a buffer memory 230. The storage controller 210 may perform communication with the non-volatile memory 220 and the buffer memory 230. The storage device 200 may include storage media for storing data in accordance with a request from the host device 100. As an example, the storage device 200 may include at least one of a solid state drive (SSD), an embedded memory, or a detachable external memory.

When the storage device 200 is a solid-state drive (SSD), the storage device 200 may be a device that complies with a non-volatile memory express (NVMe) standard. When the storage device 200 is the embedded memory or the external memory, the storage device 200 may be a device that complies with a universal flash storage (UFS) standard or an embedded multi-media card (eMMC) standard. Each of the host device 100 and the storage device 200 may generate and transmit packets according to a standard protocol that is employed.

When the non-volatile memory 220 of the storage device 200 includes a flash memory, the flash memory may include a two-dimensional (2D) NAND memory array or a three-dimensional (3D) NAND memory array, which may be referred to as a vertical NAND (VNAD) memory array. In some embodiments, the storage device 200 may include other various types of non-volatile memories. For example, the storage device 200 may include a magnetic random access memory (MRAM), a spin-transfer torque MRAM, a Conductive Bridging RAM (CBRAM), a Ferroelectric RAM (FeRAM), a Phase RAM (PRAM), a Resistive RAM and other various types of memories.

The buffer memory 230 may temporarily store data to be written in the non-volatile memory 220 or data to be read from the non-volatile memory 220. The data to be written may be transferred from the buffer memory 230 to the non-volatile memory 220.

In some embodiments, the buffer memory 230 is disposed outside the storage controller 210 and outside the non-volatile memory 220. The buffer memory 230 is implemented as a chip separate from the storage controller 210 and the non-volatile memory 220. That is, the buffer memory 230 is a semiconductor chip different from the storage controller 210 and the non-volatile memory 220. In some embodiments, the buffer memory 230, the storage controller 210 and the non-volatile memory 220 may be integrated in the same semiconductor chip. In some embodiments, the storage controller 210 may be disposed in a first semiconductor chip, and the non-volatile memory 220 may be disposed in a second semiconductor chip. In some embodiments, each of the first buffer memory 231 and the second buffer memory 232 may be disposed in a semiconductor chip separated from the first semiconductor chip of the storage controller 220 and the second semiconductor chip of the non-volatile memory 220. In some embodiments, the first buffer memory 231 may be integrated into one of the first semiconductor chip and the second semiconductor chip. In some embodiments, the second buffer memory 232 may be integrated into one of the first semiconductor chip and the second semiconductor chip. For example, both the first and second buffer memories 231 and 232 may be integrated into one of the first and second semiconductor chips. For example, the first buffer memory 231 may be integrated into one of the first and second semiconductor chips, and the second buffer memory 232 may be integrated into the other of the first and second semiconductor chips.

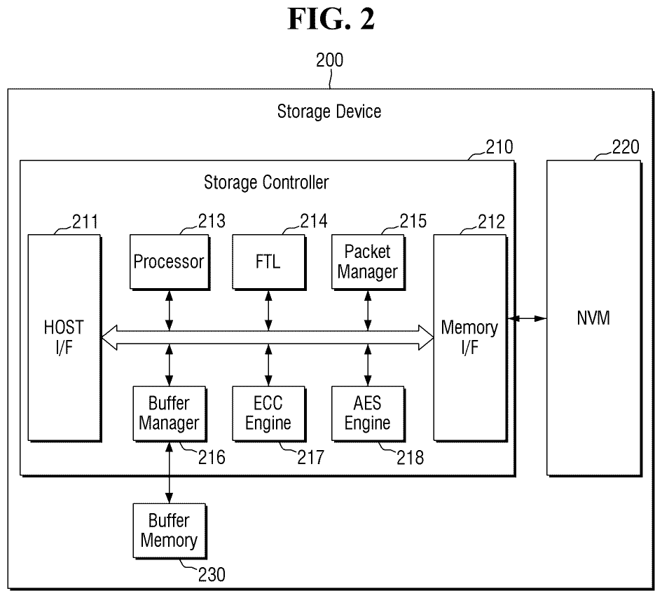

FIG. 2 is a block diagram illustrating the storage device of FIG. 1.

Referring to FIG. 2, the storage controller 210 may include a host interface 211, a memory interface 212 and a processor 213, which may perform communication with one another. The storage controller 210 may further include a flash translation layer (FTL) 214, a packet manager 215, a buffer manager 216, an error correction code (ECC) engine 217 and an advanced encryption standard (AES) engine 218, which may perform communication with one another.

The processor 213 may control an overall operation of the storage controller 210. The processor 213 may include a central processing unit or a microprocessor. The storage controller 210 may further include a working memory in which the flash translation layer (FTL) 214 is loaded, and the processor 213 may control data write and read operations for the non-volatile memory 220 by executing the flash translation layer 214.

The host interface 211 may provide an interface between the host device 100 and the storage controller 210. The host interface 211 may transmit and receive packets to and from the host device 100. The packets transmitted from the host device 100 to the host interface 211 may include a command or data to be written in the non-volatile memory 220, and the packets transmitted from the host interface 211 to the host device 100 may include a response to the command or data read from the non-volatile memory 220.

The memory interface 212 may provide an interface between the storage controller 210 and the non-volatile memory 220. The memory interface 212 may transmit the data to be written in the non-volatile memory 220 to the non-volatile memory 220, or may receive the data read from the non-volatile memory 220. The memory interface 212 may be implemented to comply with standard protocols such as Toggle or Open NAND Flash Interface (ONFI).

The flash translation layer 214 may perform various functions such as address mapping, wear-leveling and garbage collection. The address mapping operation is an operation of changing a logical address received from the host to a physical address of the non-volatile memory 220 in which data are stored. The wear-leveling is a technique for preventing excessive degradation of a specific block by allowing blocks in the non-volatile memory 220 to be used uniformly, and may exemplarily be implemented through firmware technology for balancing erase counts of physical blocks. The garbage collection is a technique for making sure of the available capacity in the non-volatile memory 220 by copying valid data of a block to a new block and then erasing the existing block.

The packet manager 215 may generate a packet according to a protocol of an interface negotiated with the host device 100, or may parse various kinds of information from the packet received from the host device 100.

The buffer manager 216 may provide an interface between the storage controller 210 and the buffer memory 230. The buffer manager 216 may temporarily store data to be written in the non-volatile memory 220 in the buffer memory 230.

The ECC engine 217 may perform error detection and correction functions for the read data read from the non-volatile memory 220. The ECC engine 217 may generate parity bits for write data to be written in the non-volatile memory 220, and the generated parity bits may be stored in the non-volatile memory 220 together with the write data. When reading the data from the non-volatile memory 220, the ECC engine 217 may correct an error of the read data by using the parity bits read from the non-volatile memory 220 together with the read data, and then may output the error-corrected read data.

The AES engine 218 may perform at least one of an encryption operation and a decryption operation performed on the data input to the storage controller 210 by using a symmetric-key algorithm.

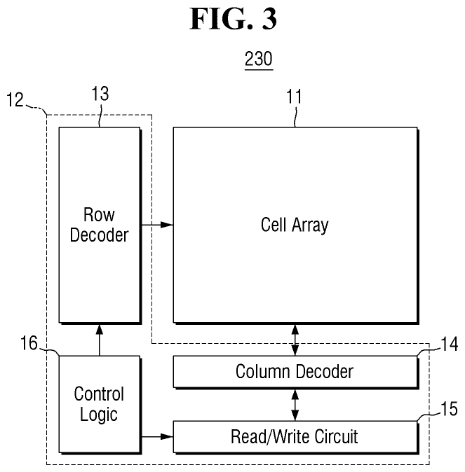

FIG. 3 is an exemplary block diagram illustrating the buffer memory of FIG. 1.

Referring to FIG. 3, the buffer memory 230 includes a cell array 11 and a peripheral circuit 12. The peripheral circuit 12 may include a row decoder 13, a column decoder 14, a read/write circuit 15, and a control logic 16. The peripheral circuit 12 is electrically connected to the cell array 11.

The cell array 11 may include a plurality of word lines and a plurality of bit lines. Memory cells may be connected to points at which the word lines cross the bit lines.

The row decoder 13 may be connected to the cell array 11 through the word lines. The row decoder 13 may decode an address input from the outside to select one of the plurality of word lines.

The column decoder 14 may be connected to the cell array 11 through the bit lines. The column decoder 14 may decode the address input from the outside to select one of the plurality of bit lines. The bit line selected by the column decoder 14 may be connected to the read/write circuit 15.

The read/write circuit 15 may provide a bit line bias for accessing the selected memory cell under the control of the control logic 16. For example, the read/write circuit 15 may provide the bit line bias to the selected bit line in order to write or read input data in or from the memory cell.

The control logic 16 may output control signals for controlling the memory in accordance with a command signal provided from the outside. The control signals output from the control logic 16 may control the read/write circuit 15.

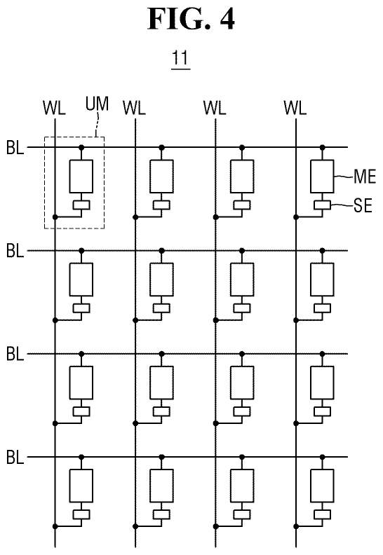

FIG. 4 is an exemplary circuit view illustrating a cell array of the buffer memory of FIG. 3.

Referring to FIGS. 3 and 4, the cell array 11 includes a plurality of bit lines BL, a plurality of word lines WL, and a plurality of memory cells UM. The buffer memory 230 includes an MRAM, and the memory cell UM is an MRAM memory cell.

The word lines WL may be extended in a first direction. The bit lines BLs may be extended in a second direction crossing the first direction to cross the word lines WL.

The memory cells UM may be arranged two-dimensionally or three-dimensionally. The respective memory cells UM may be connected to the crossing points of the word lines WL and the bit lines BL, which cross each other. Therefore, each of the memory cells UM connected to the word lines WL may be connected to the read/write circuit (e.g., 15 of FIG. 4) by the bit lines BL. Each of the memory cells UM may include a magnetic tunnel junction element ME and a selection element SE.

The magnetic tunnel junction element ME may be connected between the bit line BL and the selection element SE, and the selection element SE may be connected between the magnetic tunnel junction element ME and the word line WL. The magnetic tunnel junction element ME may include a reference layer, a free layer and a tunnel barrier layer.

The selection element SE may be configured to selectively control a flow of electric charges passing through the magnetic tunnel junction element ME. For example, the selection element SE may include at least one of a diode, a PNP bipolar transistor, an NPN bipolar transistor, an N-type Metal-Oxide-Semiconductor (NMOS) field effect transistor and a P-type Metal-Oxide-Semiconductor (PMOS) field effect transistor. When the selection element SE includes a MOS field effect transistor or a bipolar transistor, which is a three-terminal element, an additional line (e.g., source line) may be connected to the selection element SE.

When the storage device includes a buffer memory that is a volatile memory (e.g., dynamic random access memory (DRAM)), the storage device may further include a back-up non-volatile memory to protect data stored in the buffer memory in a sudden power-off situation where a power source supplied to the storage device is suddenly cut off. The data stored in the buffer memory may be backed up into the back-up non-volatile memory during such a sudden power-off. As a memory capacity of the storage device is increased, a density of the non-volatile memory 220 is increased. Therefore, a density of the buffer memory 230 should be also increased, but there is a limitation in increasing the density of the buffer memory 230 due to a limitation in a size of the storage device.

Since the storage device 200 according to some embodiments includes a buffer memory 230 that is MRAM, a back-up non-volatile memory for backing up the buffer memory 230 can be omitted. Therefore, the density of the buffer memory 230 and/or the density of the non-volatile memory 220 may be increased within the limited size of the storage device 200. In addition, the data in the buffer memory 230 may be protected during the sudden power-off even without the back-up non-volatile memory.

The amount of the data stored (moved) from the buffer memory 230 to the non-volatile memory 220 may be increased due to an increase in the density of the non-volatile memory 220 or improvement in performance of the storage controller 210. Since the storage device 200 according to some embodiments includes a buffer memory 230 that is an MRAM, a speed at which data is stored in the non-volatile memory 220 from the buffer memory 230 may be improved.

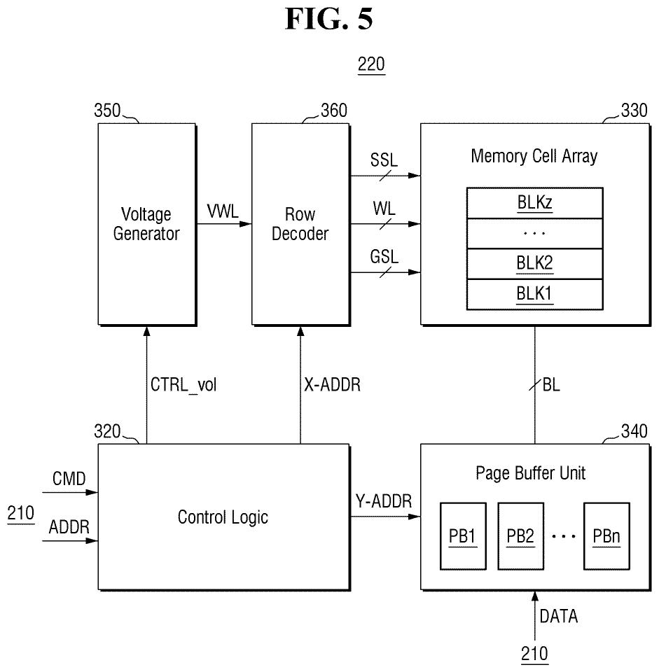

FIG. 5 is an exemplary block diagram illustrating the non-volatile memory of FIG. 1.

Referring to FIG. 5, the non-volatile memory 220 may include a control logic 320, a memory cell array 330, a page buffer unit 340, a voltage generator 350, and a row decoder 360. The non-volatile memory 220 may further include the memory interface 212 shown in FIG. 2, and may further include a column logic, a pre-decoder, a temperature sensor, a command decoder, an address decoder, and the like.

The control logic 320 may control various operations in the non-volatile memory 220. The control logic 320 may output various control signals in response to a command CMD and/or an address ADDR from the storage controller 210 (e.g., through the memory interface (212 of FIG. 2)). For example, the control logic 320 may output a voltage control signal CTRL_vol, a row address X-ADDR and a column address Y-ADDR.

The memory cell array 330 may store the data DATA provided from the storage controller 210 under the control of the control logic 320. The memory cell array 330 may output the stored data DATA to the storage controller 210 under the control of the control logic 320. The memory cell array 330 may include a plurality of memory blocks BLK1 to BLKz (z is a positive integer), each of which may include a plurality of memory cells. The memory cell array 330 may be connected to the page buffer unit 340 through the bit lines BL, and may be connected to the row decoder 360 through the word lines WL, string selection lines SSL and ground selection lines GSL.

The page buffer unit 340 may include a plurality of page buffers PB1 to PBn (n is an integer greater than or equal to 3). The plurality of page buffers PB1 to PBn may be respectively connected with the memory cells through the plurality of bit lines BL. The page buffer unit 340 may select at least one of the bit lines BL in response to the column address Y-ADDR. The page buffer unit 340 may operate as a write driver or a sense amplifier in accordance with an operation mode. For example, during a program operation, the page buffer unit 340 may apply a bit line voltage corresponding to data, which will be programmed, to the memory cells through the selected bit line. During a read operation, the page buffer unit 340 may sense a current or voltage of the selected bit line to sense data stored in the memory cell.

The voltage generator 350 may generate various voltages for performing a program operation, a read operation, and an erase operation based on the voltage control signal CTRL_vol. For example, the voltage generator 350 may generate a program voltage, a read voltage, a program verification voltage, an erase voltage and the like as word line voltages VWL.

The row decoder 360 may select one of the plurality of word lines WL in response to the row address X-ADDR, and may select one of the plurality of string selection lines SSL. For example, the row decoder 360 may apply the program voltage and the program verification voltage to the selected word line during the program operation, and may apply the read voltage to the selected word line during the read operation.

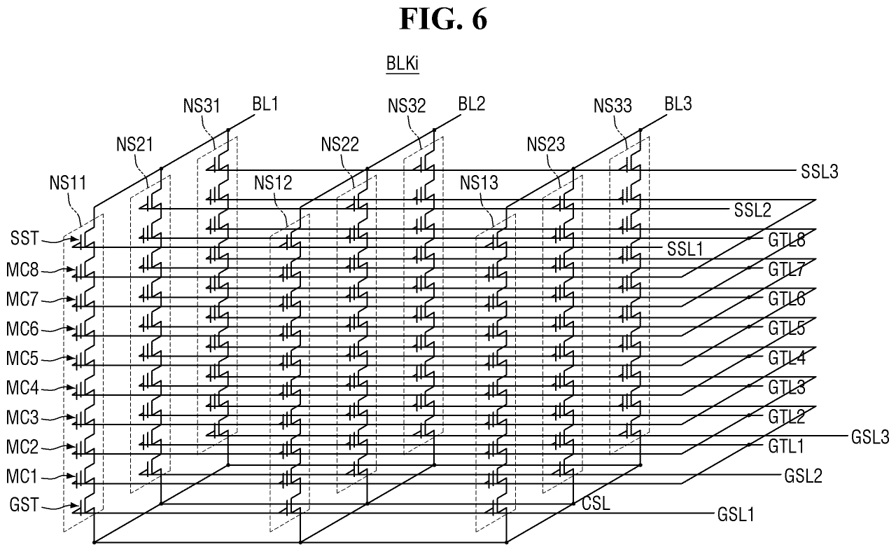

FIG. 6 is a view illustrating a 3D VNAND structure of a non-volatile memory according to some embodiments. In some embodiments, the non-volatile memory of the storage device which is implemented as a 3D VNAND type flash memory may include a plurality of memory blocks each of which includes the 3D VNAND structure of FIG. 6.

A memory block BLKi shown in FIG. 6 represents a three-dimensional memory block formed on a substrate in a three-dimensional structure. For example, a plurality of memory NAND strings included in the memory block BLKi may be formed in a direction perpendicular to the substrate.

Referring to FIG. 6, the memory block BLKi may include a plurality of memory NAND strings NS11 to NS33 connected between bit lines BL1, BL2 and BL3 and a common source line CSL. Each of the plurality of memory NAND strings NS11 to NS33 includes a string selection transistor SST, a plurality of memory cells MC1, MC2, . . . , MC8, and a ground selection transistor GST. FIG. 6 shows that each of the plurality of memory NAND strings NS11 to NS33 includes eight memory cells MC1, MC2, . . . , MC8. However, the present disclosure is not limited thereto.

The string selection transistor SST may be connected to a corresponding string selection line SSL1, SSL2 or SSL3. The plurality of memory cells MC1, MC2, . . . , MC8 may be connected to corresponding gate lines GTL1, GTL2, . . . , GTL8, respectively. The gate lines GTL1, GTL2, . . . , GTL8 may correspond to the word lines, and a portion of the gate lines GTL1, GTL2, . . . , GTL8 may correspond to a dummy word line. The ground selection transistor GST may be connected to a corresponding ground selection line GSL1, GSL2 or GSL3. The string selection transistor SST may be connected to a corresponding bit line BL1, BL2 or BL3, and the ground selection transistor GST may be connected to the common source line CSL.

The word lines (e.g., WL1) of the same height may be commonly connected, and the ground selection lines GSL1, GSL2 and GSL3 and the string selection lines SSL1, SSL2 and SSL3 may be separated from one another. Although FIG. 6 shows that the memory block BLKi is connected to eight gate lines GTL1, GTL2, . . . , GTL8 and three bit lines BL1, BL2 and BL3, the present disclosure is not limited thereto.

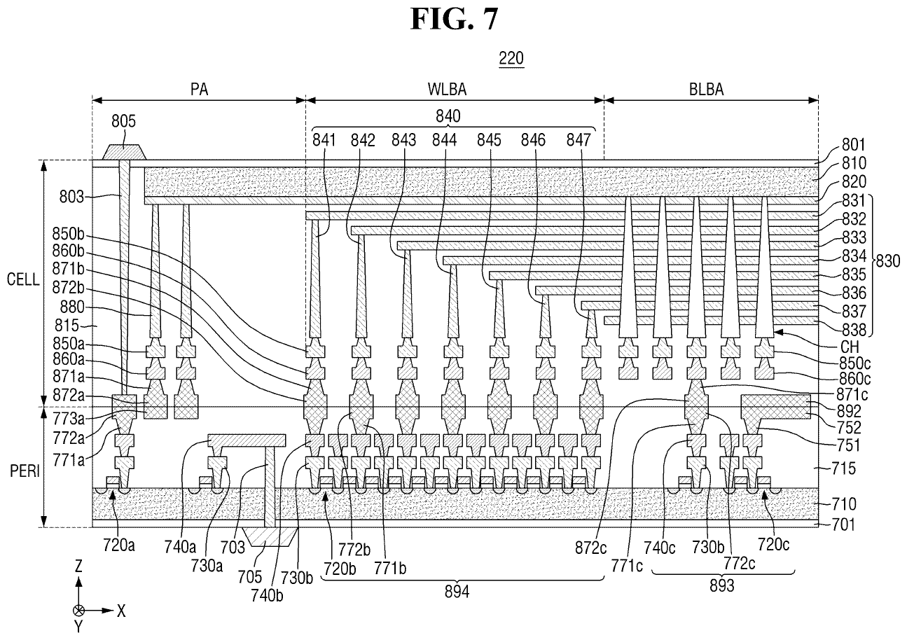

FIG. 7 is a cross-sectional view illustrating the non-volatile memory of FIG. 1.

Referring to FIG. 7, the non-volatile memory 220 may have a chip-to-chip (C2C) structure. The C2C structure may include an upper chip (i.e., an upper semiconductor chip) and a lower chip (i.e., a lower semiconductor chip) vertically stacked on each other. For example, the upper chip may include a cell region CELL which is manufactured on a first wafer, and the lower chip may include a peripheral circuit region PERI which is manufactured on a second wafer different from the first wafer. The upper chip and the lower chip may be connected to each other by a bonding method. In some embodiments, the bonding method may include electrically connecting a bonding metal formed on the uppermost metal layer of the upper chip to a bonding metal formed on the uppermost metal layer of the lower chip. The upper chip may be upside down and then bonded to the lower chip. In some embodiments, the bonding metals may be formed of copper (Cu), and the bonding method may be a Cu—Cu bonding method. For example, the bonding metals may be formed of aluminum (Al) or tungsten (W).

Each of the peripheral circuit region PERI and the cell region CELL of the non-volatile memory 220 may include an external pad bonding area PA, a word line bonding area WLBA and a bit line bonding area BLBA.

The peripheral circuit region PERI may include a first substrate 710, an interlayer insulating layer 715, a plurality of circuit elements 720a, 720b and 720c formed on the first substrate 710, first metal layers 730a, 730b and 730c connected to the plurality of circuit elements 720a, 720b and 720c, respectively, and second metal layers 740a, 740b and 740c formed on the first metal layers 730a, 730b and 730c. In some embodiments, the first metal layers 730a, 730b and 730c may be formed of tungsten having a relatively high electrical resistivity, and the second metal layers 740a, 740b and 740c may be formed of copper having a relatively low electrical resistivity. At least one metal layer may be further formed on the second metal layers 740a, 740b and 740c. At least a portion of the one or more metal layers formed on the second metal layers 740a, 740b and 740c may be formed of aluminum having an electrical resistivity lower than that of copper for forming the second metal layers 740a, 740b and 740c.

The interlayer insulating layer 715 is disposed on the first substrate 710 to cover the plurality of circuit elements 720a, 720b and 720c, the first metal layers 730a, 730b and 730c and the second metal layers 740a, 740b and 740c, and may include or may be formed of an insulating material such as silicon oxide and silicon nitride.

Lower bonding metals 771b and 772b may be formed on the second metal layer 740b of the word line bonding area WLBA. In the word line bonding area WLBA, the lower bonding metals 771b and 772b of the peripheral circuit region PERI may be electrically connected to upper bonding metals 871b and 872b of the cell region CELL by a bonding method, and the lower bonding metals 771b and 772b and the upper bonding metals 871b and 872b may be formed of aluminum, copper, or tungsten.

The cell region CELL may provide at least one memory block. The cell region CELL may include a second substrate 810 and a common source line 820. A plurality of word lines 831 to 838, which are collectively referred to as 830, may be stacked on the second substrate 810 along a third direction Z perpendicular to an upper surface of the second substrate 810. String selection lines and ground selection lines may be disposed on upper and lower portions of the word lines 830, respectively, and the plurality of word lines 830 may be disposed between the string selection lines and the ground selection line.

In the bit line bonding area BLBA, a channel structure CH may be extended in the third direction Z perpendicular to the upper surface of the second substrate 810 to pass through the word lines 830, the string selection lines and the ground selection line. The channel structure CH may include a data storage layer, a channel layer, a buried insulating layer, and the like, and the channel layer may be electrically connected to a first metal layer 850c and a second metal layer 860c. For example, the first metal layer 850c may be a bit line contact, and the second metal layer 860c may be a bit line. In some embodiments, the bit line 860c may be extended along a first direction Y parallel with the upper surface of the second substrate 810.

In some embodiments, a region in which the channel structure CH, the bit line 860c and the like are disposed may be defined as the bit line bonding area BLBA. In the bit line bonding area BLBA, the bit line 860c may be electrically connected to the circuit elements 720c, which provide a page buffer 893 in the peripheral circuit region PERI. The page buffer 893 may correspond to the page buffer unit 340 of FIG. 5. For example, the bit line 860c may be connected to the upper bonding metals 871c and 872c in the peripheral circuit region PERI, and the upper bonding metals 871c and 872c may be connected to the lower bonding metals 771c and 772c that are connected to the circuit elements 720c of the page buffer 893.

In the word line bonding area WLBA, the word lines 830 may be extended along a second direction X perpendicular to the first direction Y and parallel to the upper surface of the second substrate 810, and may be connected to a plurality of cell contact plugs 841 to 847, which may be collectively referred to as 840. The word lines 830 and the cell contact plugs 840 may be connected to each other in pads provided as at least some of the word lines 830 which are extended to have different lengths along the second direction. For example, the cell contact plugs 840 may be connected to portions of the word lines 830 which are disposed in the word line bonding area WLBA. The portions of the word lines 830 may serve as pads to which the cell contact plugs 840 are connected. In some embodiments, the word lines 830 may extend into the word line bonding area WLBA such that an upper one of the two adjacent word lines exposes a portion of a lower one of the two adjacent word lines, thereby providing a pad to which a corresponding cell contact of the cell contact plugs is connected. A first metal layer 850b and a second metal layer 860b may be sequentially connected to upper portions of the cell contact plugs 840 connected to the word lines 830. The cell contact plugs 840 may be connected to the peripheral circuit region PERI through the upper bonding metals 871b and 872b of the cell region CELL and the lower bonding metals 771b and 772b of the peripheral circuit region PERI in the word line bonding area WLBA.

The cell contact plugs 840 may be electrically connected to the circuit elements 720b for forming a row decoder 894 in the peripheral circuit region PERI. The row decoder 894 may correspond to the row decoder 360 of FIG. 5. In some embodiments, an operating voltage of the circuit elements 720b for forming the row decoder 894 may be different from an operating voltage of the circuit elements 720c for forming the page buffer 893. For example, the operating voltage of the circuit elements 720c for forming the page buffer 893 may be greater than the operating voltage of the circuit elements 720b for forming the row decoder 894.

A common source line contact plug 880 may be disposed in the external pad bonding area PA. The common source line contact plug 880 is formed of a conductive material such as a metal, a metal compound, and polysilicon, and may be electrically connected to the common source line 820. A first metal layer 850a and a second metal layer 860a may be sequentially stacked on an upper portion of the common source line contact plug 880. For example, a region in which the common source line contact plug 880, the first metal layer 850a and the second metal layer 860a are disposed may be defined as the external pad bonding area PA. The second metal layer 860a may be electrically connected to an upper metal via 871a. The upper metal via 871a may be electrically connected to an upper metal pattern 872a.

Input/output pads 705 and 805 may be disposed in the external pad bonding area PA. A lower insulating film 701 covering a lower surface of the first substrate 710 may be formed below the first substrate 710, and a first input/output pad 705 may be formed on the lower insulating film 701. The first input/output pad 705 may be connected to at least one of the plurality of circuit elements 720a, 720b and 720c disposed in the peripheral circuit region PERI through a first input/output contact plug 703, and may be separated from the first substrate 710 by the lower insulating film 701. A side insulating film may be disposed between the first input/output contact plug 703 and the first substrate 710 to electrically separate the first input/output contact plug 703 from the first substrate 710.

An upper insulating film 801 covering the upper surface of the second substrate 810 may be formed on an upper portion of the second substrate 810, and a second input/output pad 805 may be disposed on the upper insulating film 801. The second input/output pad 805 may be connected to at least one of the plurality of circuit elements 720a, 720b and 720c disposed in the peripheral circuit region PERI through a second input/output contact plug 803, a lower metal pattern 772a and a lower metal via 771a. In some embodiments, the second input/output pad 805 may be electrically connected to the circuit element 720a.

In some embodiments, the second substrate 810, the common source line 820 and the like may not be disposed in a region in which the second input/output contact plug 803 is disposed. The second input/output pad 805 may not overlap the word lines 830 in the third direction Z. The second input/output contact plug 803 may be separated from the second substrate 810 in a direction parallel to the upper surface of the second substrate 810, and may be connected to the second input/output pad 805 by passing through an interlayer insulating layer 815 of the cell region CELL.

In some embodiments, the first input/output pad 705 and the second input/output pad 805 may be selectively formed. For example, the non-volatile memory 220 may include one of the first input/output pad 705 disposed on the first substrate 710 and the second input/output pad 805 disposed on the second substrate 810. In some embodiments, the non-volatile memory 220 may include both the first input/output pad 705 and the second input/output pad 805.

In each of the external pad bonding area PA and the bit line bonding area BLBA, which are respectively included in the cell region CELL and the peripheral circuit region PERI, a metal pattern of the uppermost metal layer may exist as a dummy pattern, or the uppermost metal layer may be empty.

In the external pad bonding area PA, the non-volatile memory 220 may form a lower metal pattern 773a having the same shape as that of the upper metal pattern 872a of the cell region CELL on the uppermost metal layer of the peripheral circuit region PERI to correspond to the upper metal pattern 872a formed on the uppermost metal layer of the cell region CELL. The lower metal pattern 773a formed on the uppermost metal layer of the peripheral circuit region PERI may not be connected to a separate contact in the peripheral circuit region PERI. Similarly, in the external pad bonding area PA, an upper metal pattern having the same shape as that of the lower metal pattern of the peripheral circuit region PERI may be formed on the upper metal layer of the cell region CELL to correspond to the lower metal pattern formed on the uppermost metal layer of the peripheral circuit region PERI.

The lower bonding metals 771b and 772b may be formed on the second metal layer 740b of the word line bonding area WLBA. In the word line bonding area WLBA, the lower bonding metals 771b and 772b of the peripheral circuit region PERI may be electrically connected to the upper bonding metals 871b and 872b of the cell region CELL by a bonding method.

Also, in the bit line bonding area BLBA, an upper metal pattern 892 having the same shape as that of a lower metal pattern 752 of the peripheral circuit region PERI may be formed on the uppermost metal layer of the cell region CELL to correspond to the lower metal pattern 752 formed on the uppermost metal layer of the peripheral circuit region PERI. The lower metal pattern 752 may be electrically connected to a lower metal via 751. A contact may not be formed on the upper metal pattern 892 formed on the uppermost metal layer of the cell region CELL.

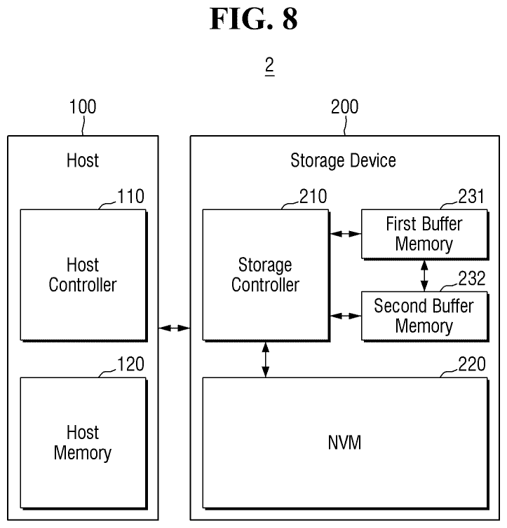

FIG. 8 is a block diagram illustrating a memory system according to some embodiments.

Referring to FIG. 8, in a memory system 2 according to some embodiments, the storage device 200 includes a plurality of buffer memories 231 and 232. For example, the storage device 200 includes a first buffer memory 231 and a second buffer memory 232. The storage controller 210, the non-volatile memory 220, the first buffer memory 231 and the second buffer memory 232 may perform communication with each other.

Each of the first buffer memory 231 and the second buffer memory 232 may correspond to the buffer memory 230 described with reference to FIGS. 1 to 4. Each of the first buffer memory 231 and the second buffer memory 232 includes the cell array 11 of FIG. 3 including MRAM memory cells UM of FIG. 4 and a peripheral circuit 12 of FIG. 3 electrically connected to the cell array 11 of FIG. 3. The peripheral circuit 12 of FIG. 3 of each of the first buffer memory 231 and the second buffer memory 232 may be independently designed depending on characteristics (i.e., operation parameters) of each of the first buffer memory 231 and the second buffer memory 232. In some embodiments, the operation parameters such as a retention period, a read speed, and a write speed may be set depending on a specific application of each of the first buffer memory 231 and the second buffer memory 232.

The first buffer memory 231 and the second buffer memory 232 are implemented as separate chips (i.e., separate semiconductor chips). That is, the first buffer memory 231 and the second buffer memory 232 are semiconductor chips different from each other in operation parameters. The first buffer memory 231 and the second buffer memory 232 may be formed through separate fabrication processes. The first buffer memory 231 and the second buffer memory 232 may be formed by their respective fabrication processes different from each other. Therefore, the arrangement of the first buffer memory 231 and the second buffer memory 232 on the semiconductor chip may be free.

In some embodiments, the first buffer memory 231 and the second buffer memory 232 are disposed outside a semiconductor chip of the storage controller 210 and outside a semiconductor chip of the non-volatile memory 220. The first buffer memory 231 and the second buffer memory 232 are implemented as chips separate from the storage controller 210 and the non-volatile memory 220. That is, the first buffer memory 231 and the second buffer memory 232 are semiconductor chips different from those of the storage controller 210 and the non-volatile memory 220. The first buffer memory 231, the second buffer memory 232, the storage controller 210 and the non-volatile memory 220 may be integrated in the same semiconductor chip.

The MRAM has excellent characteristic tunability. The storage device 200 may include buffer memories 231 and 232 that are MRAMs of which characteristics are adjusted as needed, and may flexibly use the buffer memories 231 and 232. The first buffer memory 231 and the second buffer memory 232 have their respective characteristics different from each other. The characteristics (i.e., the operation parameters) may include a speed, a retention period, and the like. For example, the second buffer memory 232 may have a different speed and/or a different retention period from the first buffer memory 231. The speed may mean, for example, a speed at which data is read and/or a speed at which data is written. For example, the write speed of the second buffer memory 232 may be slower than that of the first buffer memory 231, and the retention period of the second buffer memory 232 may be longer than that of the first buffer memory 231. For example, the characteristics (i.e., the operation parameters) of each of the buffer memories 231 and 232 may be adjusted to meet the requirements of specific applications, balancing speed, power consumption, and reliability. In some embodiments, the characteristics of the first buffer memory 231 may be adjusted to have the characteristics similar to those of a static random access memory (SRAM), and the characteristics of the second buffer memory 232 may be adjusted to have the characteristics similar to the characteristics of a NAND flash memory. There may be various methods of adjusting the characteristics of the MRAM. The number of buffer memories 231 and 232 that are MRAMs may vary.

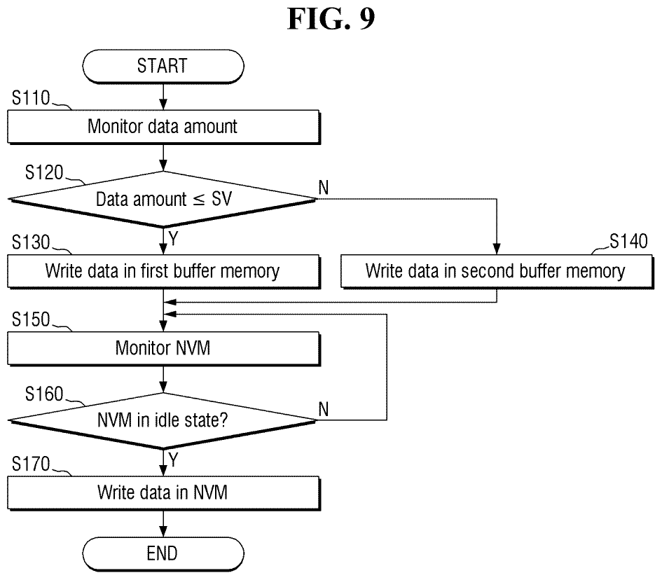

FIG. 9 is a flow chart illustrating an operation of a storage controller of FIG. 8. Referring to FIGS. 8 and 9, the amount of data is monitored (S110).

For example, the storage controller 210 may monitor the amount of data to be stored in the first buffer memory 231 or the second buffer memory 232. The amount of data is the amount of data to be temporarily stored in the first buffer memory 231 or the second buffer memory 232 by the storage controller 210, and is the amount of data to be written in the non-volatile memory 220. The amount of data may be monitored. The data may be provided from the host device 100. In some embodiments, the storage controller 210 may monitor the amount of data to be stored in the non-volatile memory 220 through one of the first buffer memory 231 and the second buffer memory 232.

It is determined whether the amount of data is less than or equal to a set value SV (S120).

When the amount of data is less than or equal to the set value SV (S120), the data is written in the first buffer memory 231 (S130). When the amount of data is not less than or equal to (i.e., is greater than) the set value SV (S120), the data is written in the second buffer memory 232 (S140).

For example, the storage controller 210 determines whether the amount of data is less than or equal to the set value SV. The storage controller 210 writes the data in the first buffer memory 231 when the amount of data is less than or equal to the set value SV, and writes the data in the second buffer memory 232 when the amount of data exceeds the set value SV. Therefore, the data is stored in the first buffer memory 231 or the second buffer memory 232. For example, the set value SV may be the storage capacity of the first buffer memory 231 (or the density of the first buffer memory 231). The storage controller 210 may write the data in the first buffer memory 231 when the amount of data is the amount that may be accommodated by the first buffer memory 231, and may write the data in the second buffer memory 232 when the amount of data is the amount that cannot be accommodated by the first buffer memory 231. The storage controller 210 may determine, for example, based on the amount of data signals received through the host interface 211, whether the amount of data is less than or equal to the set value SV.

The non-volatile memory 220 is monitored (S150). It is determined whether the non-volatile memory 220 is in an idle state (S160).

For example, the storage controller 210 may monitor the non-volatile memory 220 and determine whether the non-volatile memory 220 is in an idle state. When internal operations of the non-volatile memory 220 are not performed or are completed, the storage controller 210 may determine that the non-volatile memory 220 is in an idle state. The internal operations may include, for example, a write operation and a read operation. For example, when the storage controller 210 receives a ready/busy output signal (e.g., high level) indicating a ready state from the non-volatile memory 220, the storage controller 210 may determine that the non-volatile memory 220 is in an idle state.

When the non-volatile memory 220 is in an idle state (S160), the data stored in the first buffer memory 231 or the second buffer memory 232 is written in the non-volatile memory 220 (S170). When the non-volatile memory 220 is not in an idle state (S160), the step S150 of monitoring the status of the non-volatile memory 220 is performed.

For example, when the non-volatile memory 220 is in an idle state, the storage controller 210 may write the data written in the first buffer memory 231 or the second buffer memory 232 in the non-volatile memory 220. Therefore, the data is stored in the non-volatile memory 220. The data written in the first buffer memory 231 or the second buffer memory 232 may be written in the non-volatile memory 220 and then deleted.

In some embodiments, the storage device 200 includes a first buffer memory 231 having a faster speed and a second buffer memory 232 having a longer retention period, and uses one of the first buffer memory 231 and the second buffer memory 232 as a buffer memory depending on the amount of data to be stored in the non-volatile memory 220 from the storage controller 210. Therefore, the speed of the storage device 200 may be improved.

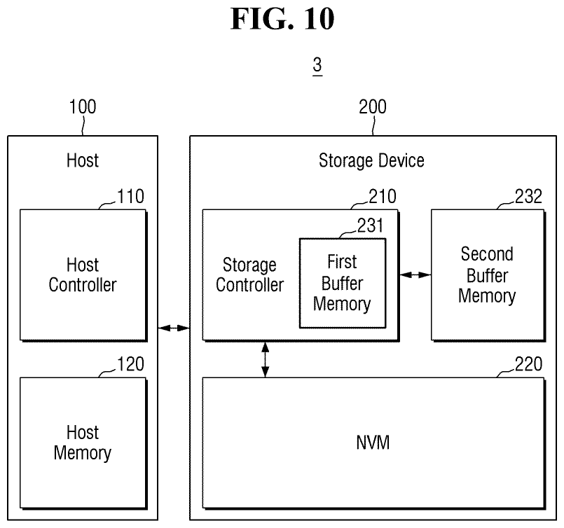

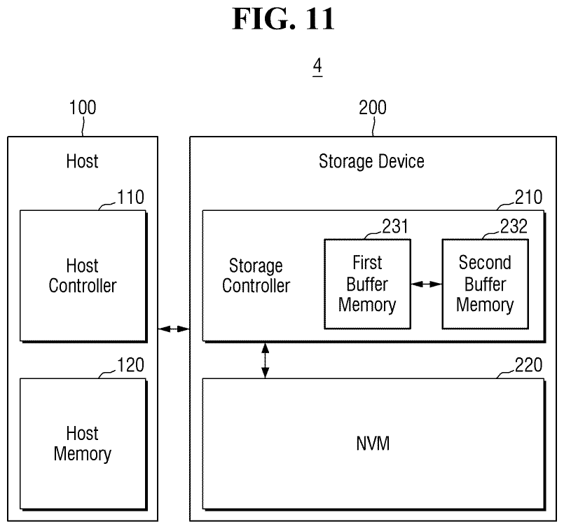

FIGS. 10 and 11 are block diagrams illustrating a memory system according to some embodiments. For convenience of description, redundant portions of those described with reference to FIGS. 1 to 9 will be briefly described or omitted.

Referring to FIGS. 10 and 11, at least one of the plurality of buffer memories 231 and 232 is disposed inside the storage controller 210.

Referring to FIG. 10, in a memory system 3 according to some embodiments, the first buffer memory 231 is disposed inside the storage controller 210, and the second buffer memory 232 is disposed outside the storage controller 210 and outside the non-volatile memory 220. The first buffer memory 231 is included in the storage controller 210. The first buffer memory 231 may be embedded in the storage controller 210. For example, the first buffer memory 231 may be integrated into a semiconductor chip of the storage controller 210. Unlike the second buffer memory 232, which is disposed in a separate semiconductor chip electrically connected to a semiconductor chip of the storage controller 210, the first buffer memory 231 may be part of a semiconductor chip in which the storage controller 210 is disposed.

Unlike the above example, the second buffer memory 232 may be disposed inside the storage controller 210, and the first buffer memory 231 may be disposed outside the storage controller 210 and outside the non-volatile memory 220.

Referring to FIG. 11, in a memory system 4 according to some embodiments, the first buffer memory 231 and the second buffer memory 232 are disposed in the storage controller 210. The first buffer memory 231 and the second buffer memory 232 are included in the storage controller 210. The first buffer memory 231 and the second buffer memory 232 are embedded in the storage controller 210. For example, the first buffer memory 231 and the second buffer memory 232 may be integrated into a semiconductor chip of the storage controller 210. In some embodiments, a third buffer memory may be outside a semiconductor chip of the storage controller 210 and a semiconductor chip of the non-volatile memory 220. Unlike the third buffer memory, which is a separate semiconductor chip electrically connected to a semiconductor chip of the storage controller 210, the first buffer memory 231 and the second buffer memory 232 may be part of a semiconductor chip of the storage controller 210.

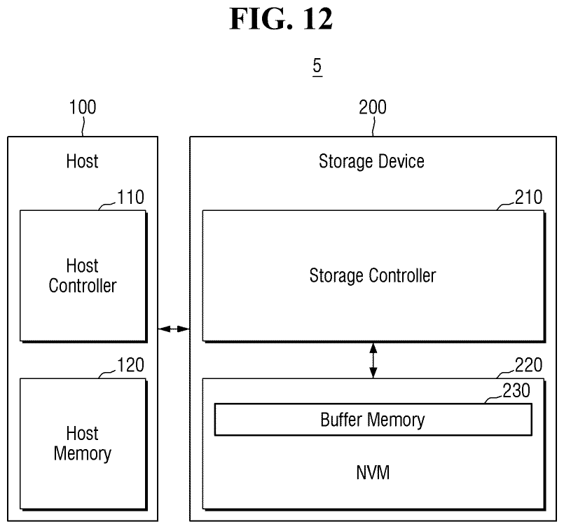

FIG. 12 is a block diagram illustrating a memory system according to some embodiments. For convenience of description, redundant portions of those described with reference to FIGS. 1 to 7 will be briefly described or omitted.

Referring to FIG. 12, the buffer memory 230 is disposed inside the non-volatile memory 220. The buffer memory 230 is included in the non-volatile memory 220. The buffer memory 230 is embedded in the non-volatile memory 220. For example, the buffer memory 230 may be integrated into a semiconductor chip of the non-volatile memory 220. In some embodiments, another buffer memory may be outside a semiconductor chip of the storage controller 210 and a semiconductor chip of the non-volatile memory 220. Unlike another buffer memory, which is a separate semiconductor chip electrically connected to the semiconductor chip of the storage controller 210, the buffer memory 230 may be part of the semiconductor chip of the non-volatile memory 220.

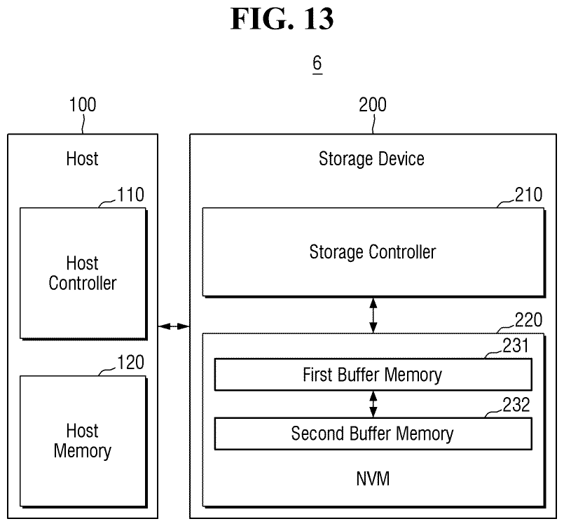

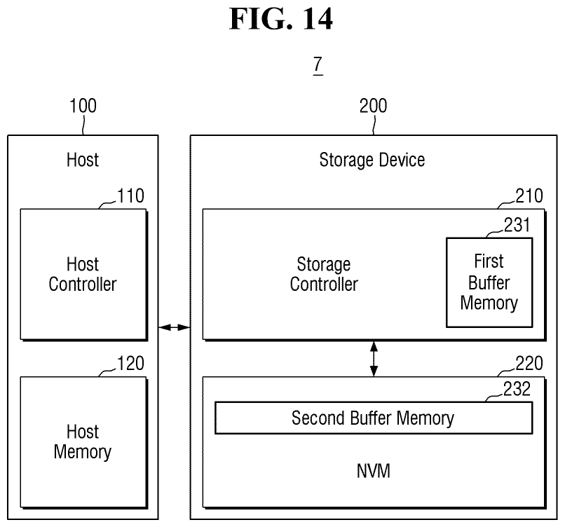

FIGS. 13 and 14 are block diagrams illustrating a memory system according to some embodiments. For convenience of description, redundant portions of those described with reference to FIGS. 1 to 9 will be briefly described or omitted.

Referring to FIGS. 13 and 14, at least one of the plurality of buffer memories 231 and 232 is disposed inside the non-volatile memory 220.

Referring to FIG. 13, in a memory system 6 according to some embodiments, the first buffer memory 231 and the second buffer memory 232 are disposed inside the non-volatile memory 220. The first buffer memory 231 and the second buffer memory 232 are included in the non-volatile memory 220. The first buffer memory 231 and the second buffer memory 232 are embedded in the non-volatile memory 220. For example, the first buffer memory 231 and the second buffer memory 232 may be integrated into a semiconductor chip of the non-volatile memory 220. In some embodiments, a third buffer memory may be outside a semiconductor chip of the storage controller 210 and a semiconductor chip of the non-volatile memory 220. Unlike the third buffer memory, which is a separate semiconductor chip electrically connected to a semiconductor chip of the storage controller 210, the first buffer memory 231 and the second buffer memory 232 may be part of the semiconductor chip of the non-volatile memory 220.

Referring to FIG. 14, in a memory system 7 according to some embodiments, the first buffer memory 231 is disposed inside the storage controller 210, and the second buffer memory 232 is disposed inside the non-volatile memory 220. The storage controller 210 includes the first buffer memory 231, and the non-volatile memory 220 includes the second buffer memory 232. The first buffer memory 231 is embedded in the storage controller 210, and the second buffer memory 232 is embedded in the non-volatile memory 220. For example, the first buffer memory 231 may be integrated into a first semiconductor chip of the storage controller 210, and the second buffer memory 232 may be integrated into a second semiconductor chip of the non-volatile memory 220. In some embodiments, a third buffer memory may be outside the first semiconductor chip of the storage controller 210 and the second semiconductor chip of the non-volatile memory 220. Unlike the third buffer memory, which is a separate semiconductor chip electrically connected to the first semiconductor chip of the storage controller 210, the first buffer memory 231 may be part of the first semiconductor chip of the storage controller 210, and the second buffer memory 232 may be part of the second semiconductor chip of the non-volatile memory 220. The second semiconductor chip may be separated from the first semiconductor chip.

Unlike the above example, the second buffer memory 232 may be disposed inside the storage controller 210, and the first buffer memory 231 may be disposed inside the non-volatile memory 220.

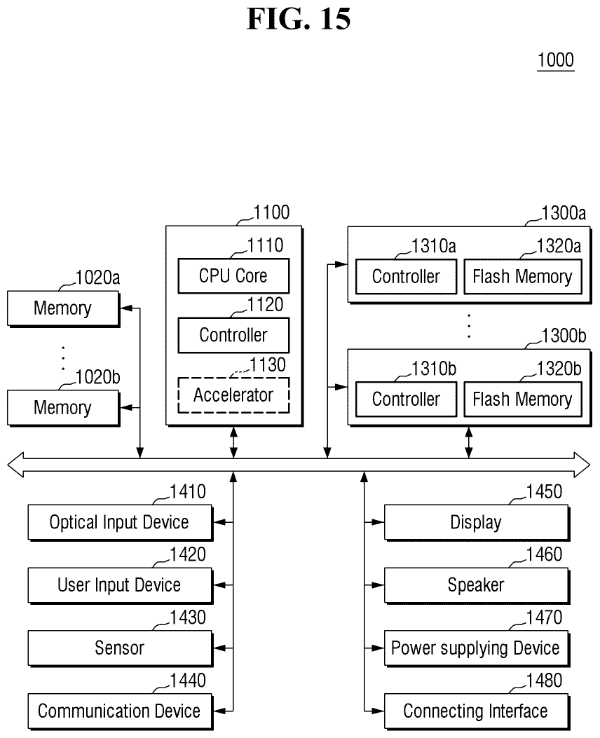

FIG. 15 is a view illustrating a system according to some embodiments.

A system 1000 of FIG. 15 may be a mobile system such as a mobile phone, a smart phone, a tablet personal computer (PC), a wearable device, a healthcare device or an Internet of things (IoT) device. However, the system 1000 of FIG. 15 is not necessarily limited to the mobile system, and may be a personal computer, a laptop computer, a server, a media player or an automotive device such as navigator.

Referring to FIG. 15, the system 1000 may include a main processor 1100, memories 1200a and 1200b and storage devices 1300a and 1300b, and may further include one or more of an image capturing device 1410, a user input device 1420, a sensor 1430, a communication device 1440, a display 1450, a speaker 1460, a power supplying device 1470, and a connecting interface 1480.

The main processor 1100 may control the overall operation of the system 1000, in more detail the operation of other elements constituting the system 1000. The main processor 1100 may be implemented as a general purpose processor, a dedicated processor, or an application processor.

The main processor 1100 may include one or more CPU cores 1110, and may further include a controller 1120 for controlling the memories 1200a and 1200b and/or the storage devices 1300a and 1300b. In accordance with the embodiment, the main processor 1100 may further include an accelerator 1130 that is a dedicated circuit for high-speed data computation such as an artificial intelligence (AI) data computation. The accelerator 1130 may include a graphics processing unit (GPU), a neural processing unit (NPU), and/or a data processing unit (DPU), and may be implemented as a separate chip physically independent of other elements of the main processor 1100.

The memories 1200a and 1200b may be used as main memory devices of the system 1000, and may include a volatile memory such as an SRAM and/or a DRAM but may also include a non-volatile memory such as a flash memory, a PRAM, and/or an RRAM. The memories 1200a and 1200b may be implemented in the same package as the main processor 1100.

The storage devices 1300a and 1300b may serve as non-volatile storage devices for storing data regardless of whether a power source is supplied, and may have a storage capacity relatively greater than that of the memories 1200a and 1200b. In some embodiments, the storage devices 1300a and 1300b may include the above-described storage device (200 of FIGS. 1 to 14). Storage controllers 1310a and 1310b and non-volatile storages 1320a and 1320b may correspond to the storage controller 210 and the non-volatile memory 220 of FIGS. 1 to 14, respectively.

The storage devices 1300a and 1300b may be included in the system 1000 in a physically separated chip from the main processor 1100, and may be implemented in the same package as the main processor 1100. In some embodiments, the storage devices 1300a and 1300b may be detachably coupled to other elements of the system 1000 through an interface, such as the connecting interface 1480, which will be described later, by having the same form as that of a memory card.

The image capturing device 1410 may capture a still image or a video, and may be a camera, a camcorder and/or a webcam.

The user input device 1420 may receive various types of data input from a user of the system 1000, and may be a touch pad, a keypad, a keyboard, a mouse and/or a microphone.

The sensor 1430 may sense various types of physical quantities that may be acquired from the outside of the system 1000, and convert the sensed physical quantities into an electrical signal. The sensor 1430 may be a temperature sensor, a pressure sensor, an illuminance sensor, a position sensor, an acceleration sensor, a biosensor and/or a gyroscope sensor.

The communication device 1440 may perform transmission and reception of signals between other devices outside the system 1000 in accordance with various communication protocols. Such a communication device 1440 may be implemented by including an antenna, a transceiver and/or a modem.

The display 1450 and the speaker 1460 may serve as output devices that output visual information and auditory information to a user of the system 1000, respectively.

The power supplying device 1470 may appropriately convert power supplied from an external power source and/or a battery (not shown) embedded in the system 1000 to supply the power to each element of the system 1000.

The connecting interface 1480 may provide connection between the system 1000 and an external device connected to the system 1000 to exchange data with the system 1000. The connecting interface 1480 may be implemented in a variety of interface ways such as an Advanced Technology Attachment (ATA), Serial ATA (SATA), external SATA (e-SATA), Small Computer Small Interface (SCSI), Serial Attached SCSI (SAS), Peripheral Component Interconnection (PCI), PCI express (PCIe), NVM express (NVMe), IEEE 1394, universal serial bus (USB), Secure Digital (SD) card, Multi-Media Card (MMC), embedded multi-media card (eMMC), Universal Flash Storage (UFS), embedded Universal Flash Storage (eUFS), and Compact Flash (CF) card interface.

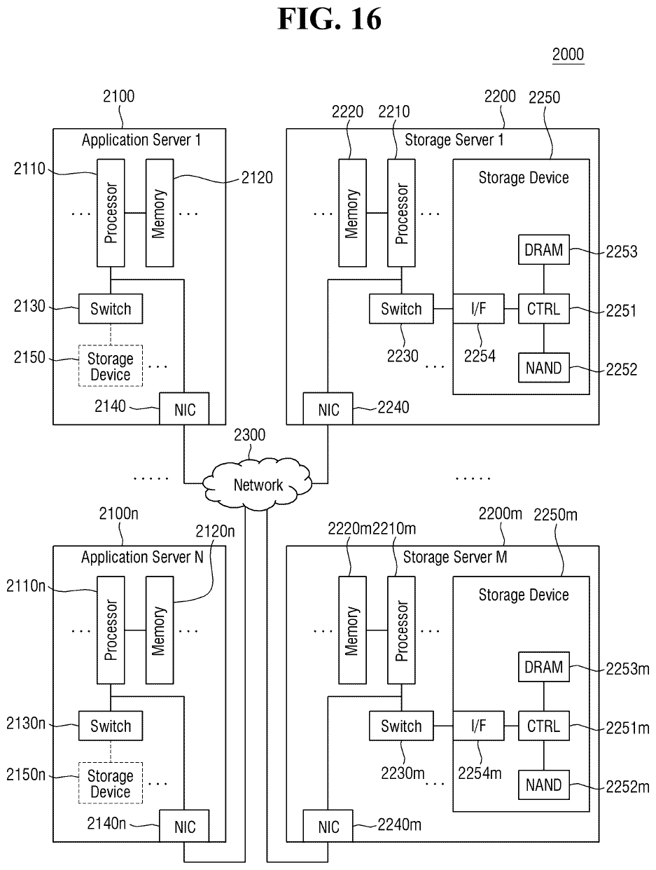

FIG. 16 is a view illustrating a data center according to some embodiments.

Referring to FIG. 11, a data center 2000 is a facility for providing a service by collecting various data, and may be referred to as a data storage center. The data center 2000 may be a system for a search engine or a database operation, and may be a computing system used in an enterprise such as a bank or a government agency. The data center 2000 may include application servers 2100 to 2100n and storage servers 2200 to 2200m. The number of application servers 2100 to 2100n and the number of storage servers 2200 to 2200m may be variously selected in accordance with embodiments, and the number of application servers 2100 to 2100n and the number of storage servers 2200 to 2200m may be different from each other.

The application server 2100 or the storage server 2200 may include at least one of the processors 2110 and 2210 or the memories 2120 and 2220. The storage server 2200 will be described by way of example. The processor 2210 may control the overall operation of the storage server 2200, and may access the memory 2220 to execute command languages and/or data loaded into the memory 2220. The memory 2220 may be a Double Data Rate Synchronous DRAM (DDR SDRAM), a High Bandwidth Memory (HBM), a Hybrid Memory Cube (HMC), a Dual In-line Memory Module (DIMM), an Optane DIMM, and/or a Non-Volatile DIMM (NVMDIMM). In accordance with the embodiment, the number of processors 2210 and the number of memories 2220, which are included in the storage server 2200, may be variously selected.

In some embodiments, the processor 2210 and the memory 2220 may provide a processor-memory pair. In some embodiments, the number of processors 2210 and the number of memories 2220 may be different from each other. The processor 2210 may include a single core processor or a multi-core processor. The description of the storage server 2200 may be similarly applied to the application server 2100. In accordance with the embodiment, the application server 2100 may not include the storage device 2250. The storage server 2200 may include at least one storage device 2250. The number of storage devices 2250 included in the storage server 2200 may be variously selected in accordance with the embodiments. In some embodiments, the above-described storage device (200 of FIGS. 1 to 14) may be mounted in or detached from the storage server 2200, which is the host, in the form of one storage device 2250.

The application servers 2100 to 2100n and the storage servers 2200 to 2200m may perform communication with each other through a network 2300. The network 2300 may be implemented using a Fibre Channel (FC) or Ethernet. In this case, the FC is a medium used for relatively high-speed data transmission, and may use an optical switch that provides high performance/high availability. In accordance with an access scheme of the network 2300, the storage servers 2200 to 2200m may be provided as file storages, block storages or object storages.

In some embodiments, the network 2300 may be a storage-only network such as a storage area network (SAN). For example, the SAN may be an FC-SAN that uses an FC network and is implemented in accordance with an FC protocol (FCP). For another example, the SAN may be an IP-SAN that uses a TCP/IP network and is implemented in accordance with an SCSI over TCP/IP or Internet SCSI (iSCSI) protocol. In another embodiment, the network 2300 may be a general network such as a TCP/IP network. For example, the network 2300 may be implemented in accordance with protocols such as FC over Ethernet (FCOE), Network Attached Storage (NAS) and NVMe over Fabrics (NVMe-oF).

Hereinafter, the description will be based on the application server 2100 and the storage server 2200. The description of the application server 2100 may be applied to other application server 2100n, and the description of the storage server 2200 may be applied to other storage server 2200m.

The application server 2100 may store data requested by a user or a client in one of the storage servers 2200 to 2200m through the network 2300. Also, the application server 2100 may acquire the data requested by the user or the client from one of the storage servers 2200 to 2200m through the network 2300. For example, the application server 2100 may be implemented as a web server or a database management system (DBMS).

The application server 2100 may access the memory 2120n or the storage device 2150n, which is included in other application server 2100n, through the network 2300. Alternatively, the application server 2100 may access the memories 2220 to 2220m or the storage devices 2250 to 2250m, which are included in the storage servers 2200 to 2200m, through the network 2300. Therefore, the application server 2100 may perform various operations for the data stored in the application servers 2100 to 2100n and/or the storage servers 2200 to 2200m. For example, the application server 2100 may execute command languages for moving or copying data between the application servers 2100 to 2100n and/or the storage servers 2200 to 2200m. In this case, the data may be moved from the storage devices 2250 to 2250m of the storage servers 2200 to 2200m to the memories 2220 to 2220m of the storage servers 2200 to 2200m, or may be directly moved to the memories 2120 to 2120n of the application servers 2100 to 2100n. The data moved through the network 2300 may be data encrypted for security or privacy.

The storage server 2200 will be described by way of example. The interface 2254 may provide physical connection of the processor 2210 and a controller 2251 and physical connection of a Network InterConnect (NIC) 2240 and the controller 2251. For example, the interface 2254 may be implemented in a Direct Attached Storage (DAS) scheme that directly connects the storage device 2250 to a dedicated cable. Also, for example, the interface 2254 may be implemented in the variety of interface ways of the connecting interface 1480, which are described with reference to FIG. 15.

The storage server 2200 may further include a switch 2230 and an NIC 2240. The switch 2230 may selectively connect the processor 2210 with the storage device 2250 in accordance with the control of the processor 2210, or may selectively connect the NIC 2240 with the storage device 2250.

In some embodiments, the NIC 2240 may include a network interface card, a network adapter, and the like. The NIC 2240 may be connected to the network 2300 by a wired interface, a wireless interface, a Bluetooth interface, an optical interface, and the like. The NIC 2240 may include an internal memory, a Digital Signal Processor (DSP), a host bus interface, and the like, and may be connected to the processor 2210 and/or the switch 2230 through the host bus interface. The host bus interface may be implemented as one of the above-described examples of the interface 2254. In some embodiments, the NIC 2240 may be integrated with at least one of the processor 2210, the switch 2230 or the storage device 2250.

In the storage servers 2200 to 2200m or the application servers 2100 to 2100n, the processor may transmit a command to the storage devices 2130 to 2130n and 2250 to 2250m or the memories 2120 to 2120n and 2220 to 2220m to program or read data. At this time, the data may be error-corrected data through an Error Correction Code (ECC) engine. The data may be Data Bus Inversion (DBI) or Data Masking (DM) processed data, and may include Cyclic Redundancy Code (CRC) information. The data may be data encrypted for security or privacy.

In some embodiments, the storage devices 2150 to 2150n and 2250 to 2250m may include the above-described storage device (200 of FIGS. 1 to 14). Each of the controller 2251 and a NAND flash 2252 may correspond to the storage controller 210 and the storage device 200 of FIGS. 1 to 14. The controller 2251 may further include a Static Random Access Memory (SRAM). For example, a write command and/or a read command may be provided from the processor 2210 in the storage server 2200, the processor 2210 in the other storage server 2200m or the processors 2110 and 2110n in the application servers 2100 and 2100n. The DRAM 2253 may temporarily store (buffer) data to be written in the NAND flash 2252 or data read from the NAND flash 2252. Also, the DRAM 2253 may store metadata. In this case, the metadata is user data or data generated by the controller 2251 to manage the NAND flash 2252. The storage device 2250 may include a Secure Element (SE) for security or privacy.

Although the embodiments of the present disclosure have been described with reference to the accompanying drawings, it will be apparent to those skilled in the art that the present disclosure can be manufactured in various forms without being limited to the above-described embodiments and can be embodied in other specific forms without departing from technical spirits and essential characteristics of the present disclosure. Thus, the above embodiments are to be considered in all respects as illustrative and not restrictive.

What is claimed is:

1. A storage device comprising:
a first buffer memory and a second buffer memory that are different from each other in at least one operation parameter;
a non-volatile memory; and
a storage controller connected to the first buffer memory, the second buffer memory, and the non-volatile memory and configured to perform communication with the first buffer memory, the second buffer memory and the non-volatile memory,
wherein each of the first buffer memory and the second buffer memory includes Magnetic Random Access Memory (MRAM) cells and a peripheral circuit configured to operate the MRAM cells according to the at least one operation parameter.

2. The storage device of claim 1,
wherein the first buffer memory and the second buffer memory are separate semiconductor chips that are disposed outside a first semiconductor chip in which the storage controller is disposed and a second semiconductor chip in which the non-volatile memory is disposed.

3. The storage device of claim 1,
wherein the first buffer memory is integrated into a first semiconductor chip in which the storage controller is disposed, and
wherein the second buffer memory is disposed in a semiconductor chip separated from the first semiconductor chip in which the storage controller is disposed and a second semiconductor chip in which the non-volatile memory is disposed.

4. The storage device of claim 1,
wherein the first buffer memory and the second buffer memory are integrated into a first semiconductor chip in which the storage controller is disposed.

5. The storage device of claim 1,
wherein the first buffer memory and the second buffer memory are integrated into a second semiconductor chip in which the non-volatile memory is disposed.

6. The storage device of claim 1,
wherein the first buffer memory is integrated into a first semiconductor chip in which the storage controller is disposed, and the second buffer memory is integrated into a second semiconductor chip in which the non-volatile memory is disposed.

7. The storage device of claim 1,
wherein the at least one operation parameter includes a first retention period of the first buffer memory and a second retention period of the second buffer memory, and
wherein the first retention period is different from the second retention period.

8. The storage device of claim 1,
wherein the first buffer memory and the second buffer memory are disposed in separate semiconductor chips, respectively.

9. The storage device of claim 1,
wherein the storage controller is configured to store data provided from a host into the non-volatile memory via one of the first buffer memory and the second buffer memory.

10. A storage device comprising:
a first buffer memory including first MRAM memory cells operating at a first operation parameter;
a second buffer memory including second MRAM memory cells operating at a second operation parameter;
a non-volatile memory; and
a storage controller configured to store data, which is provided from a host, in one of the first buffer memory and the second buffer memory in accordance with an amount of the data provided from the host.

11. The storage device of claim 10,
wherein the storage controller is configured to:
determine whether an amount of the data exceeds a set value;
store, in response to determining that the amount of the data does not exceed the set value, in the first buffer memory; and
store, in response to determining of the amount of the data exceeding the set value, the data in the second buffer memory,
wherein the first operation parameter includes a first write speed of the first buffer memory,
wherein the second operation parameter includes a second write speed of the second buffer memory, and
wherein the first write speed is faster than the second write speed.

12. The storage device of claim 11,
wherein the first buffer memory is integrated into a first semiconductor chip of the storage controller.

13. The storage device of claim 10,
wherein the storage controller is configured to:
determine whether the non-volatile memory is in an idle state, and
store, in response to determining of the non-volatile memory being in the idle state, the data stored in one of the first buffer memory and the second buffer memory in the non-volatile memory.

14. The storage device of claim 10,
wherein the first buffer memory and the second buffer memory are disposed in separate chips, respectively,
wherein the first operation parameter includes a first writing speed and a first retention period,
wherein the second operation parameter include a second writing speed and a second retention period,
wherein the first writing speed is faster than the second writing speed, and
wherein the first retention period is shorter than the second retention period.

15. The storage device of claim 10,
wherein the first buffer memory and the second buffer memory are disposed in separate semiconductor chips, respectively, which are disposed outside a first semiconductor chip of the storage controller and a second semiconductor chip of the non-volatile memory.

16. The storage device of claim 10,
wherein at least one of the first buffer memory and the second buffer memory is integrated into a first semiconductor chip of the storage controller.

17. The storage device of claim 10,
wherein at least one of the first buffer memory and the second buffer memory is integrated into a second semiconductor chip of the non-volatile memory.

18. A storage device comprising:
a first buffer memory including first MRAM memory cells operating at a first writing speed;
a second buffer memory including second MRAM memory cells operating at a second writing speed;
a non-volatile memory; and
a storage controller configured to perform communication with the first buffer memory, the second buffer memory, and the non-volatile memory,
wherein the first writing speed is different from the second writing speed.

19. The storage device of claim 18,
wherein each of first buffer memory and the second buffer memory includes a peripheral circuit.

20. The storage device of claim 18,
wherein at least one of the first buffer memory and the second buffer memory is incorporated into a first semiconductor chip of the storage controller or a second semiconductor chip of the non-volatile memory.
